(19) United States
(12) Patent Application Publication
(10) Pub. No.: US 2023/0411559 A1
(43) Pub. Date: Dec. 21, 2023

(54) RED MICRO LED DISPLAY PANEL AND SEPARATED PANEL DISPLAY DEVICE HAVING THE SAME

(71) Applicant: HON HAI PRECISION INDUSTRY CO., LTD., New Taipei City (TW)

(72) Inventor: Te-En TSENG, Taipei City (TW)

(21) Appl. No.: 17/817,638

(22) Filed: Aug. 4, 2022

(30) Foreign Application Priority Data
May 30, 2022 (TW) 111120099

(51) Int. Cl. H01L 33/38; H01L 33/10; H01L 33/50; H01L 27/15

(52) U.S. Cl. CPC H01L 33/382; H01L 27/156; H01L 33/505; H01L 33/10

(57) ABSTRACT

The present disclosure provides a red micro LED display panel applied in a separated panel display device. The red micro LED display panel includes a driving back plane, an electrode array, a UV micro LED, and a red quantum dot layer. The electrode array is located on the driving back plane. The UV micro LED is located on the electrode array. The red quantum dot layer is located on the UV micro LED.

### CROSS-REFERENCE TO RELATED APPLICATION

This application claims priority to Taiwan Application Serial Number 111120099, filed May 30, 2022, which is herein incorporated by reference in its entirety.

### BACKGROUND

### Field of Invention

The present invention relates to a red micro LED display panel and a separated panel display device.

### Description of Related Art

Due to the minimization of the micro LED display device, the EQE of the micro LED reduces when the size of the display device becomes smaller. For example, in a display device having red, blue, and green colors. It is difficult to improve the EQE of the red micro LED. In some separated panel display device, a mixed material (e.g., quaternary compound) or nanopillar structures are used to manufacture a red micro LED display panel. However, such method has many disadvantages such as high cost, low efficiency, and low yield.

Accordingly, it is still a development direction for the industry to provide a red micro LED display panel which can improve those problems mentioned above.

### SUMMARY

One aspect of the present disclosure is a red micro LED display panel applied in a separated panel display device.

In some embodiments, the red micro LED display panel includes a driving back plane, an electrode array, a UV micro LED, and a red quantum dot layer. The electrode array is located on the driving back plane. The UV micro LED is located on the electrode array. The red quantum dot layer is located on the UV micro LED.

In some embodiments, the UV micro LED is configured to emit an UV light, and a wavelength of the UV light is in a range from 405 nm to 430 nm.

In some embodiments, the red micro LED display panel includes multiple pixels, and a size of each of the pixels is smaller than 6 um.

In some embodiments, the red micro LED display panel includes a light shielding layer located on the UV micro LED, and the light shield layer includes a plurality of spacers located in the red quantum dot layer.

In some embodiments, the red micro LED display panel includes an interval between adjacent two of the spacers is smaller than 6 um.

In some embodiments, each of the spacers includes an inclined angle, and the inclined angle is in a range from 0 degree to 30 degrees.

In some embodiments, a thickness of the red quantum dot layer is smaller than 5 um.

In some embodiments, the red micro LED display panel includes a Bragg reflection layer located on the red quantum dot layer.

In some embodiments, the red micro LED display panel includes a red color filter layer located on the red quantum dot layer.

Another aspect of the present disclosure is a separated panel display device.

In some embodiments, the separated panel display device includes a red micro LED display panel, a green micro LED display panel, and a blue micro LED display panel. The red micro LED display panel includes a driving back plane, an electrode array, a UV micro LED, and a red quantum dot layer. The electrode array is located on the driving back plane. The UV micro LED is located on the electrode array. The red quantum dot layer is located on the micro LED.

Another aspect of the present disclosure is a red micro LED display panel applied in a separated panel display device.

In some embodiments, the red micro LED display panel includes a driving back plane, an electrode array, a micro LED, and a red quantum dot layer. The electrode array is located on the driving back plane. The micro LED is located on the electrode array, and the micro LED is configured to emit a light, and a wavelength of the light is in a range from 405 nm to 430 nm. The red quantum dot layer is located on the micro LED.

In some embodiments, the red micro LED display panel includes multiple pixels, and a size of each of the pixels is smaller than 6 um.

In some embodiments, the red micro LED display panel includes a light shielding layer located on the UV micro LED, and the light shield layer includes a plurality of spacers located in the red quantum dot layer.

In some embodiments, an interval between adjacent two of the spacers is smaller than 6 um.

In some embodiments, each of the spacers includes an inclined angle, and the inclined angle is in a range from 0 degree to 30 degrees.

In some embodiments, a material of each of the spacers comprises metal.

In some embodiments, a material of each of the spacers includes an epoxy layer and a metal layer, and the metal layer wraps the epoxy layer.

In some embodiments, a thickness of the red quantum dot layer is smaller than 5 um.

In some embodiments, the red micro LED display panel includes a Bragg reflection layer located on the red quantum dot layer.

In some embodiments, the red micro LED display panel includes a red color filter layer located on the red quantum dot layer.

In the aforementioned embodiments, the red micro LED display panel of the separated panel display device of the present disclosure can enhance the conversion efficiency of the quantum dots by using the UV micro LED and the red quantum dot layer. As such, the red micro LED display panel, the green micro LED display panel, and the blue micro LED display panel of the separated panel display device all have sufficient external quantum efficiency to achieve requirements of a full color display device. By emitting an UV light having a wavelength in a range from 405 nm to 430 nm by the UV micro LED 130, both the conversion efficiency and the stability of the quantum dots can be optimized.

### BRIEF DESCRIPTION OF THE DRAWINGS

The invention can be more fully understood by reading the following detailed description of the embodiment, with reference made to the accompanying drawings as follows:

FIG. 1 is a schematic of a separated panel display device according to one embodiment of the present disclosure;

FIG. 2 is a partial cross-sectional view of a red micro LED display panel in FIG. 1;

FIG. 3 is a graph of an absorption coefficient and the excitation light wavelength of a quantum dot material according to one embodiment of the present disclosure;

FIG. 4 is a graph of light wavelength and light intensity according to one embodiment of the present disclosure;

FIG. 5 is a graph of pixel size and External Quantum Efficiency according to another embodiment of the present disclosure;

FIG. 6 is partial cross-sectional view of a green micro LED display panel according to one embodiment of the present disclosure;

FIG. 7 is partial cross-sectional view of a blue micro LED display panel according to one embodiment of the present disclosure;

FIG. 8 is a partial cross-sectional view of a red micro LED display panel according to another embodiment of the present disclosure; and

FIG. 9 is a partial cross-sectional view of a red micro LED display panel according to another embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

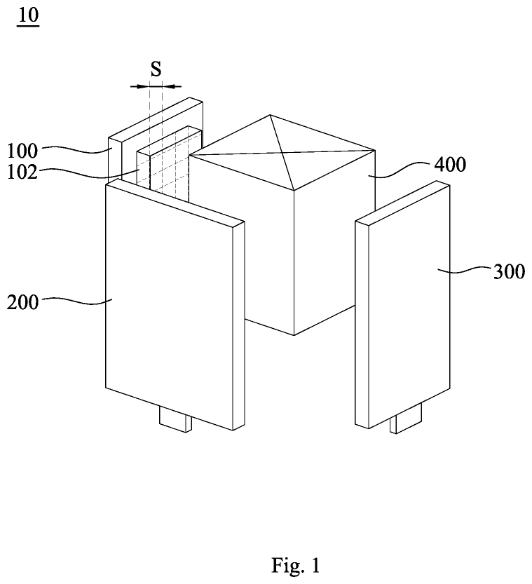

FIG. 1 is a schematic of a separated panel display device 10 according to one embodiment of the present disclosure. The separated panel display device 10 includes a red micro LED display panel 100, a green micro LED display panel 200, and a blue micro LED display panel 300. The separated panel display device 10 further includes a beam splitter 400. The red micro LED display panel 100, the green micro LED display panel 200, and the blue micro LED display panel 300 face each other and surround the beam splitter 400. A red light, a green light, and a blue light respectively from the red micro LED display panel 100, the green micro LED display panel 200, and the blue micro LED display panel 300 travel towards the same direction after combined by the beam splitter 400.

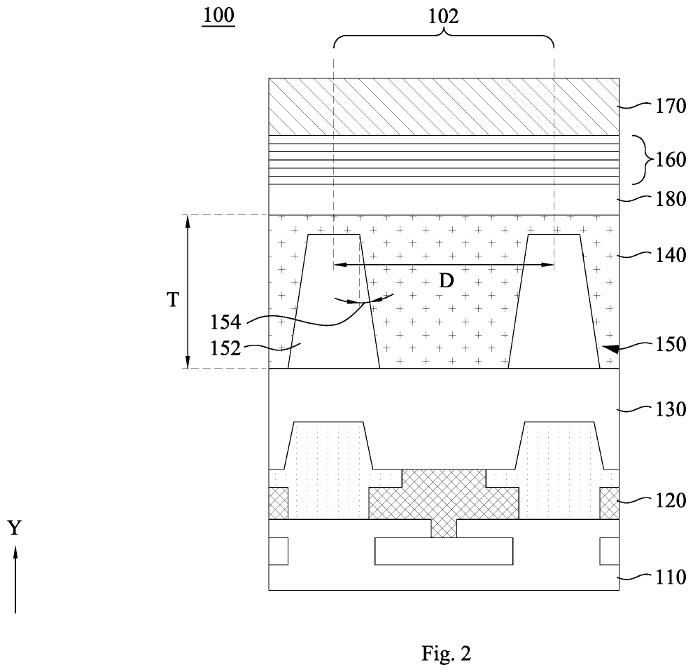

FIG. 2 is a partial cross-sectional view of a red micro LED display panel 100 in FIG. 1. The red micro LED display panel 100 includes a driving back plane 110, an electrode array 120, a UV micro LED 130, and a red quantum dot layer 140. The electrode array 120 is located on the driving back plane 110. The UV micro LED 130 is located on the electrode array 120. The red quantum dot layer 140 is located on the UV micro LED 130.

Reference is made to FIG. 1 and FIG. 2, the red micro LED display panel 100 includes multiple pixels 102, and there is only one pixel 102 demonstrated in FIG. 2 as an example. The display panels with different colors of the separated panel display device 10 are separated from each other. That is, the elements on the driving back plane 110 are only used to emit a red light. The elements on the green micro LED display panel 200 and the blue micro LED display panel 300 are also respectively used to emit a green light and a blue light.

Reference is made to FIG. 2. The UV micro LED 130 includes a GaN epitaxy layer as an emitting layer. The UV micro LED 130 is configured to emit an UV light, and a wavelength of the UV light is in a range from 405 nm to 430 nm. The UV light emitted from the UV micro LED 130 excites the red quantum dots in the red quantum dot layer 140 such that red lights emitted from the red quantum dots travel along an outlet direction Y.

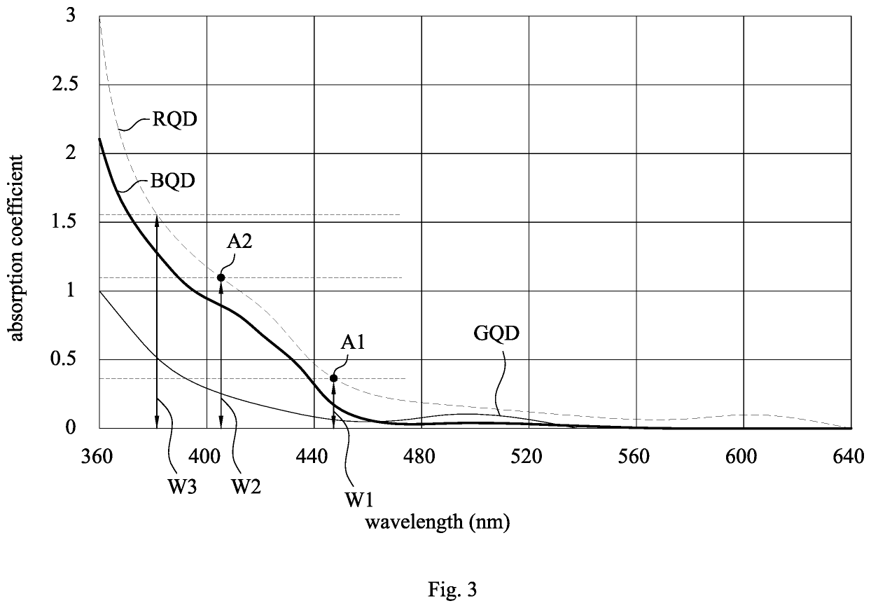

FIG. 3 is a graph of an absorption coefficient of a quantum dot material and the excitation light wavelength according to one embodiment of the present disclosure. The curve RQD represents the absorption coefficient of red quantum dots which are excited by lights with different wavelengths. The curve GQD and the curve BQD respectively represent the absorption coefficients of green quantum dots and blue quantum dots which are excited by lights with different wavelengths. The absorption coefficients of the red quantum dots, the green quantum dots, and the blue quantum dots corresponding to the UV light wavelength are all higher than the absorption coefficients of the red quantum dots, the green quantum dots, and the blue quantum dots corresponding to the blue light wavelength. The absorption coefficients corresponding to the wavelength W1, the wavelength W2, and the wavelength W3 are labeled in FIG. 3. The wavelength W1 corresponds to blue light wavelength, the wavelength W2 and the wavelength W3 correspond to UV light wavelengths. It can be seen in FIG. 3 that the absorption coefficient of the quantum dots corresponding to the UV light are two to four times higher than the absorption coefficient of the quantum dots corresponding to the blue light.

For example, by using a blue light having a wavelength of 450 nm (wavelength W1) as an example, the absorption coefficient A1 of the red quantum dots corresponding to wavelength W1 is about 0.35˜0.4. By using a UV light having a wavelength of 415 nm (wavelength W2) as an example, the absorption coefficient A2 of the red quantum dots corresponding to wavelength W2 is about 1.1. In the present embodiment, the Photoluminescence Quantum yield (PLQY) of the red quantum dots corresponding to the UV light and the blue light is substantially maintained in a range from 70% to 75%. The conversion efficiency of the red quantum dots can be derived from the product of the PLQY and the absorption coefficient of the red quantum dots.

According to FIG. 2 and FIG. 3, the red micro LED display panel 100 of the present disclosure can use the UV micro LED 130 to excite the red quantum dot layer 140 to enhance the conversion efficiency of the quantum dots. As such, the red micro LED display panel 100, the green micro LED display panel 200, and the blue micro LED display panel 300 of the separated panel display device 10 shown in FIG. 1 all have sufficient external quantum efficiency (EQE) to achieve requirements of a full color display device.

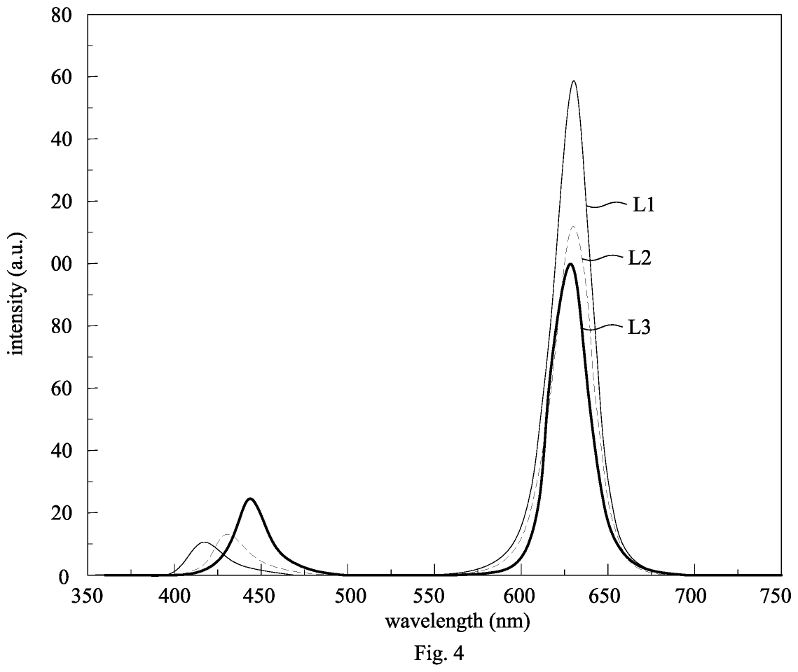

FIG. 4 is a graph of light wavelength and light intensity according to one embodiment of the present disclosure. The curve L1, the curve L2, and the curve L3 respectively represent the intensity of red light emitted from the red quantum dots and the light intensity of unreacted light, and the red quantum dots are respectively excited by the UV lights having wavelengths of 410 nm and 430 nm and the blue light having a wavelength of 450 nm. Based on the peak value corresponding to the wavelength of 625 nm, the intensity of red light excited by the UV light having a wavelength of 410 nm denoted by the curve L1 is the highest. Based on the peak values corresponding to the wavelengths of 405 nm and 450 nm, the light intensity of the unreacted UV light having a wavelength of 410 nm denoted by the curve L1 is the lowest. It can be known by comparing the curve L1 and the curve L3, the intensity of red light excited by the UV light having a wavelength of 410 nm is about 60% higher than the intensity of red light excited by the blue light having a wavelength of 450 nm, and a ratio of the light intensity of the unreacted UV light having a wavelength of 410 nm is about 40% of the ratio of the light intensity of the unreacted blue light having a wavelength of 450 nm. Based on the definition of the absorbance, the logarithm of the intensity of red light divided by the light intensity of the unreacted UV light having a wavelength of 410 nm is about 1.89. The logarithm of the intensity of red light divided by the light intensity of the unreacted blue light having a wavelength of 450 nm is about 1.65. Accordingly, the efficiency of exciting the red quantum dots by the UV micro LED 130 is higher. Therefore, the red micro LED display panel 100 of the present disclosure can use the UV micro LED 130 to excite the red quantum dot layer 140 to enhance the conversion efficiency of the quantum dots.

In the present embodiment, the conversion efficiency of the red quantum dots can be improved to a range of about 50% to 60%. The UV light having a wavelength smaller than 450 nm may damage the quantum dots, and the UV light having a wavelength greater than 430 nm may reduce the absorption efficiency of the quantum dots. Therefore, by emitting the UV light having the wavelength in a range from 405 nm to 430 nm by the UV micro LED 130, both the conversion efficiency and the stability of the quantum dots can be optimized.

Reference is made to FIG. 2. The red micro LED display panel 100 further includes a light shielding layer 150 located on the UV micro LED 130. The light shield layer 150 includes multiple spacers 152. The spacers 152 are located between adjacent two of the pixels 102 to avoid cross-talk. In the present embodiment, the material of the spacers 152 includes metal such as aluminum or other high reflectance metal, but the present discloser is not limited thereof. The spacers 152 have an inclined angle 154. The inclined angle 154 is defined as an angle between a surface facing the pixel 102 and the outlet direction Y. The inclined angle 154 of the present disclosure is in a range from to 30 degrees. As an example, the inclined angle 154 in the present embodiment is 15 degrees. Since the spacers 152 includes metal and has the inclined angle 154, a portion of the red light emitting towards the spacers 152 can be reflected by the spacers 152 and travel towards the outlet direction Y when the quantum dots in the red quantum dot layer 140 are excited by the UV light.

As shown in FIG. 1, a size of each of the pixels 102 of the present embodiment is smaller than 6 um. As shown in FIG. 2, the size S of the pixels 102 can be defined by the interval D between adjacent two of the spacers 152. In other words, the interval D of adjacent two of the spacers 152 of the present embodiment is smaller than 6 um.

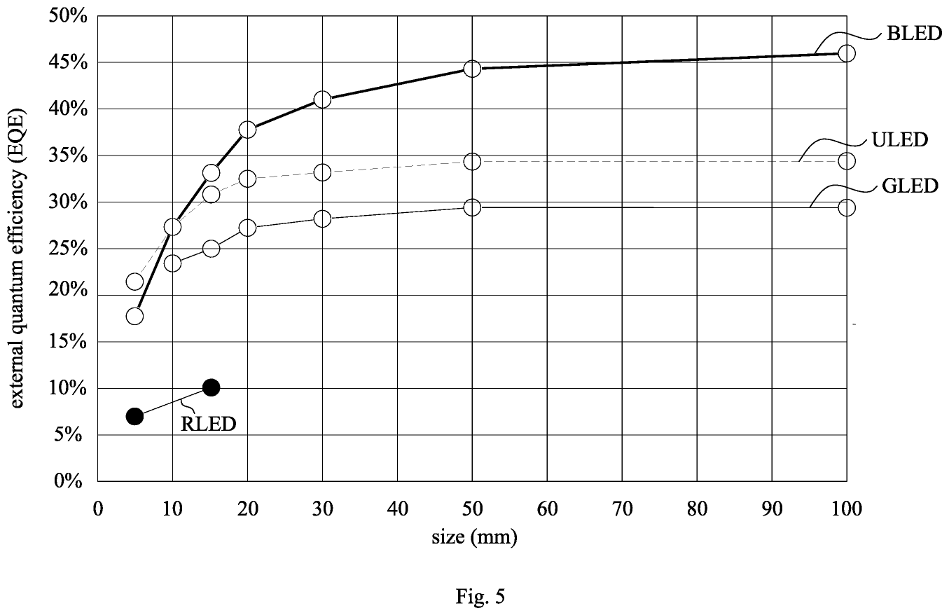

FIG. 5 is a graph of pixel size and External Quantum Efficiency according to another embodiment of the present disclosure. The curve BLED represents the relation between the pixel size and EQE of a blue micro LED. The curve ULED represents the relation between the pixel size and EQE of a UV micro LED. The curve GLED represents the relation between the pixel size and EQE of a green micro LED. The curve RLED represents the relation between the pixel size and EQE of a red micro LED. According to FIG. 5, when the pixel size is greater 10 um, EQE of the blue micro LED is the highest. However, according to the curve ULED, EQE of the UV micro LED is higher than the EQE of the blue micro LED when the pixel size is smaller than 10 um. Accordingly, by using the UV micro LED 130 in a device whose pixel size is smaller than 6 um, more light energy can be used to excite the quantum dots so as to enhance the conversion efficiency.

Reference is made to FIG. 2. In the present embodiment, a thickness T of the red quantum dot layer 140 is smaller than 5 um. Specifically, when the thickness T of the red quantum dot layer 140 is thicker, the quantum dot conversion efficiency is higher. However, the thicker the red quantum dot layer 140, the higher the spacers 152 are required to avoid cross-talk. When the pixel size is reduced under 6 um and the red quantum dot layer 140 is thicker, the aspect ratio of the spacers 152 needs to be higher and the inclined angle 154 needs to be maintained to prevent the outlet opening (i.e., the distance between adjacent two spacers 152) of the UV micro LED 130 being blocked. Therefore, in the pixel 102 under 6 um, it is more difficult to form the spacers 152 which satisfy those conditions mentioned above. Therefore, by using the UV light to excite the quantum dots in the red quantum dot layer 140 to improve the conversion efficiency can reduce the thickness of the red quantum dot layer 140. As such, the required aspect ratio of the spacers 152 can be reduced, and therefore the difficulty of manufacturing process of the light shielding layer 150 can be reduced.

The red micro LED display panel 100 further includes a Bragg reflection layer 160, a red color filter layer 170, and a planarization layer 180. The planarization layer 180 is located on the red quantum dot layer 140. The Bragg reflection layer 160 is located on the planarization layer 180. The red color filter layer 170 is located on the Bragg reflection layer 160. By disposing the planarization layer 180 on the red quantum dot layer 140 and the light shielding layer 150, a flat surface is provided for disposing the Bragg reflection layer 160. The Bragg reflection layer 160 is a stack of multiple layers having different material with different refractive index. The Bragg reflection layer 160 is configured to reflect the UV light transmitting through the red quantum dot layer 140. As such, the UV light that is not absorbed by the quantum dots can be reflected back to the red quantum dot layer 140 to excite the quantum dots again, and therefore the UV transmittance is reduced and the usage rate of the UV light is increased. The red color filter layer 170 can filter the light transmitting through the Bragg reflection layer 160 such that the red light emitted from the red micro LED display panel 100 is in a certain wavelength spectrum. For example, the unreacted UV light may transmit through the Bragg reflection layer 160 and travel along the outlet direction Y. The red color filter layer 170 can filter this portion of the UV light to enhance the purity of the red light emitted from the red micro LED display panel 100.

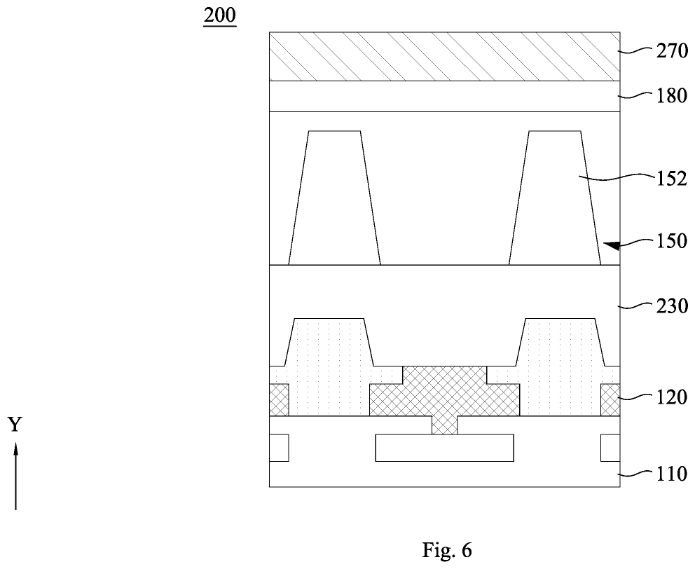

FIG. 6 is partial cross-sectional view of a green micro LED display panel 200 according to one embodiment of the present disclosure. The green micro LED display panel 200 and the red micro LED display panel 100 have the same driving back plane 110, the electrode array 120, the light shielding layer 150, and the planarization layer 180. The green micro LED display panel 200 has no quantum dot layer. The green micro LED display panel 200 has a green micro LED 230. The green micro LED 230 includes a GaN epitaxy layer as an emitting layer. The green micro LED display panel 200 includes a green color filter layer 270 to enhance the purity of the green light emitted from the green micro LED display panel 200.

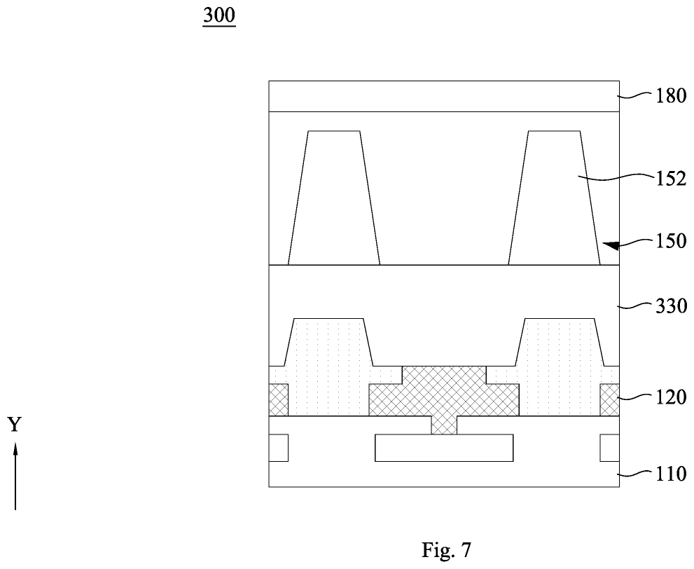

FIG. 7 is partial cross-sectional view of a blue micro LED display panel 300 according to one embodiment of the present disclosure. The blue micro LED display panel 300 and the red micro LED display panel 100 have the same driving back plane 110, the electrode array 120, the light shielding layer 150, and the planarization layer 180. The blue micro LED display panel 300 has no quantum dot layer. The blue micro LED display panel 300 has a blue micro LED 330. The blue micro LED 330 includes a GaN epitaxy layer as an emitting layer.

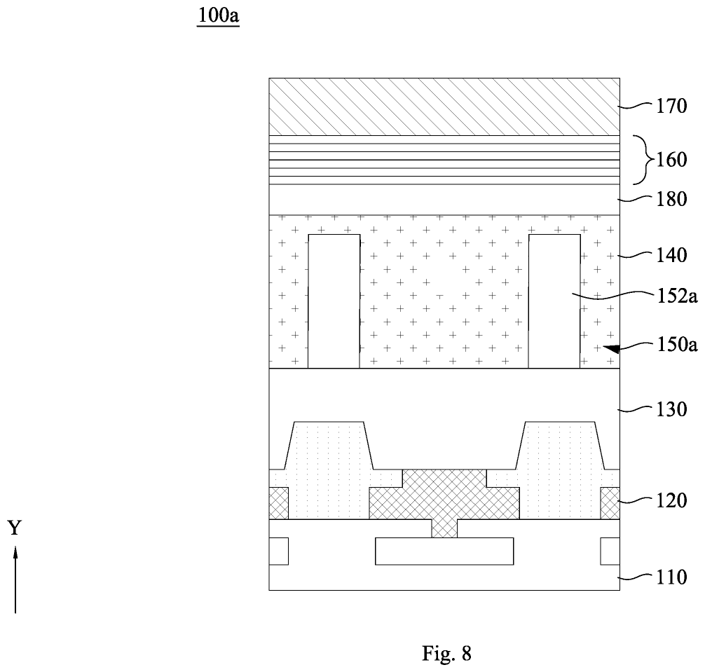

FIG. 8 is a partial cross-sectional view of another red micro LED display panel 100a according to another embodiment of the present disclosure. The red micro LED display panel 100a is substantially the same as the red micro LED display panel 100 shown in FIG. 2, and the difference is the configuration of the spacers 152a of the light shielding layer 150a of the red micro LED display panel 100a. The spacers 152a have an inclined angle close to 0 degree. In other words, the shape of the spacers 152a in the present embodiment is close to a rectangular such that the amount of the UV light emitted from the UV micro LED 130 to the red quantum dot layer 140 is increased. The red micro LED display panel 100a and the red micro LED display panel 100 shown in FIG. 2 have the same advantages, and therefore the description is not repeated hereinafter.

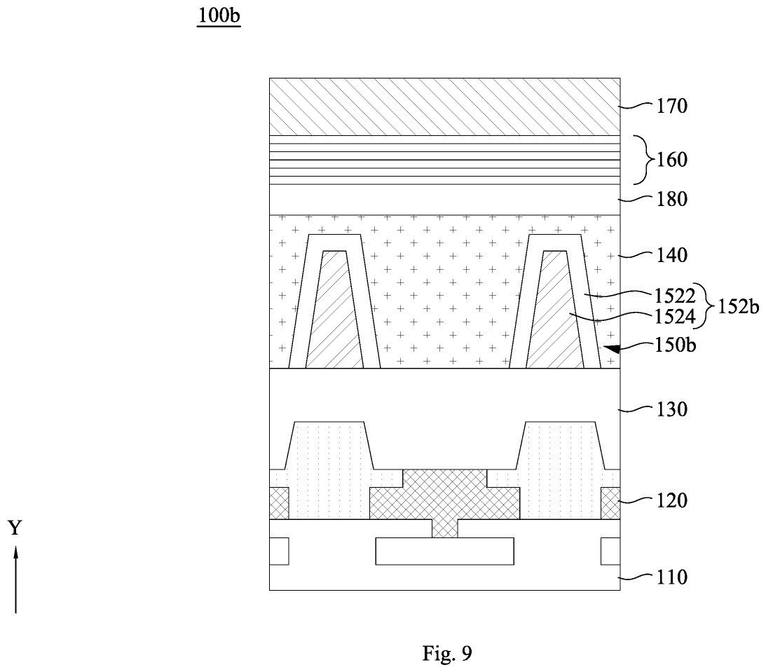

FIG. 9 is a partial cross-sectional view of a red micro LED display panel 100b according to another embodiment of the present disclosure. The red micro LED display panel 100b is substantially the same as the red micro LED display panel 100 shown in FIG. 2, and the difference is the configuration of the spacers 152b of the light shielding layer 150b of the red micro LED display panel 100b. The spacers 152b include a metal layer 1522 and an epoxy layer 1524. The metal layer 1522 wraps the epoxy layer 1524. That is, the spacers 152b are formed by coating the metal layer 1522 outside the epoxy layer 1524. In other words, the light shielding layer 150b of the red micro LED display panel 100b is a composite shielding layer. The red micro LED display panel 100b and the red micro LED display panel 100 shown in FIG. 2 have the same advantages, and therefore the description is not repeated hereinafter.

In summary, the red micro LED display panel of the separated panel display device of the present disclosure can enhance the conversion efficiency of the quantum dots by using the UV micro LED and the red quantum dot layer. As such, the red micro LED display panel, the green micro LED display panel, and the blue micro LED display panel of the separated panel display device all have sufficient external quantum efficiency to achieve requirements of a full color display device. By emitting an UV light having a wavelength in a range from 405 nm to 430 nm by the UV micro LED 130, both the conversion efficiency and the stability of the quantum dots can be optimized. Since the EQE of the UV micro LED is higher than the EQE of the blue micro LED when the pixel size is smaller than 6 um, more light energy can be used to excite the quantum dots so as to enhance conversion efficiency by using the UV micro LED. The Bragg reflection layer of the red micro LED display panel can reflect the UV light transmitting through the red quantum dot layer to excite the quantum dots again, and therefore the UV transmittance is reduced and the usage rate of the UV light is increased.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A red micro LED display panel, applied in a separated panel display device, wherein the red micro LED display panel comprises:
a driving back plane;
an electrode array located on the driving back plane;
an UV micro LED located on the electrode array; and
a red quantum dot layer located on the UV micro LED.

2. The red micro LED display panel of claim 1, wherein the UV micro LED is configured to emit an UV light, and a wavelength of the UV light is in a range from 405 nm to 430 nm.

3. The red micro LED display panel of claim 1, further comprising:
a plurality of pixels, wherein a size of each of the pixels is smaller than 6 um.

4. The red micro LED display panel of claim 1, further comprising:
a light shielding layer located on the UV micro LED, wherein the light shield layer comprises a plurality of spacers located in the red quantum dot layer.

5. The red micro LED display panel of claim 4, wherein an interval between adjacent two of the spacers is smaller than 6 um.

6. The red micro LED display panel of claim 4, wherein each of the spacers comprises an inclined angle, and the inclined angle is in a range from 0 degree to 30 degrees.

7. The red micro LED display panel of claim 1, wherein a thickness of the red quantum dot layer is smaller than 5 um.

8. The red micro LED display panel of claim 1, further comprising:
a Bragg reflection layer located on the red quantum dot layer.

9. The red micro LED display panel of claim 1, further comprising:
a red color filter layer located on the red quantum dot layer.

10. A separated panel display device, comprising:
a red micro LED display panel, comprising:
a driving back plane;
an electrode array located on the driving back plane;
an UV micro LED located on the electrode array; and
a red quantum dot layer located on the UV micro LED;
a green micro LED display panel comprising a green micro LED; and
a blue micro LED display panel comprising a blue micro LED.

11. A red micro LED display panel, applied in a separated panel display device, wherein the red micro LED display panel comprises:
a driving back plane;
an electrode array located on the driving back plane;
a micro LED located on the electrode array, wherein the micro LED is configured to emit a light, and a wavelength of the light is in a range from 405 nm to 430 nm; and
a red quantum dot layer located on the micro LED.

12. The red micro LED display panel of claim 11, further comprising:
a plurality of pixels, wherein a size of each of the pixels is smaller than 6 um.

13. The red micro LED display panel of claim 11, further comprising:
a light shielding layer located on the micro LED, wherein the light shield layer comprises a plurality of spacers located in the red quantum dot layer.

14. The red micro LED display panel of claim 13, wherein an interval between adjacent two of the spacers is smaller than 6 um.

15. The red micro LED display panel of claim 13, wherein each of the spacers comprises an inclined angle, and the inclined angle is in a range from 0 degree to 30 degrees.

16. The red micro LED display panel of claim 13, wherein a material of each of the spacers comprises metal.

17. The red micro LED display panel of claim 13, wherein a material of each of the spacers comprises an epoxy layer and a metal layer, and the metal layer wraps the epoxy layer.

18. The red micro LED display panel of claim 11, wherein a thickness of the red quantum dot layer is smaller than 5 um.

19. The red micro LED display panel of claim 11, further comprising:
a Bragg reflection layer located on the red quantum dot layer.

20. The red micro LED display panel of claim 11, further comprising:
a red color filter layer located on the red quantum dot layer.
